(19) United States
(12) Patent Application Publication
(10) Pub. No.: US 2026/0262381 A1
(43) Pub. Date: Sep. 3, 2026

(54) DISPLAY DEVICE

(71) Applicant: Sharp Display Technology Corporation, Kameyama City, Mie (JP)

(72) Inventors: Tadayoshi MIYAMOTO, Kameyama City (JP); Yoshinobu NAKAMURA, Kameyama City (JP); Sohtaroh TANAKA, Kameyama City (JP)

(21) Appl. No.: 19/163,139

(22) PCT Filed: May 18, 2023
(86) PCT No.: PCT/JP2023/018571

§ 371 Date: Sep. 8, 2025

(51) Int. Cl. H10K 59/121

(52) U.S. Cl. CPC H10K 59/1213

(57) ABSTRACT

A complementary metal oxide semiconductor circuit is a combination of a first TFT having a first semiconductor layer formed of polysilicon and a second TFT having a second semiconductor layer formed of oxide semiconductor. The complementary metal oxide semiconductor circuit includes, in a plan view, at least one of a first protective pattern formed of the oxide semiconductor around the first semiconductor layer of the first TFT or a second protective pattern formed of the polysilicon around the second semiconductor layer of the second TFT.

### TECHNICAL FIELD

The disclosure relates to a display device.

### BACKGROUND ART

In recent years, light-emitting organic electroluminescence (EL) display devices using organic EL elements have attracted attention as a replacement for liquid crystal display devices. An organic EL display device is provided with a plurality of thin-film transistors (hereinafter also referred to as “TFTs”) for each of subpixels. A subpixel is a minimum unit of an image. Here, examples of a well-known semiconductor layer for a TFT include: a semiconductor layer made of polysilicon having high mobility; and a semiconductor layer made of oxide semiconductor such as In—Ga—Zn—O and exhibiting low current leakage.

For example, Patent Document 1 discloses a display device having a hybrid structure in which a first TFT made of polysilicon semiconductor and a second TFT made of oxide semiconductor are formed on a substrate.

### CITATION LIST

### Patent Literature

[Patent Document 1] Japanese Unexamined Patent Application Publication No. 2020-017558

### SUMMARY

### Technical Problem

As to the hybrid organic EL display device including subpixels each provided with a TFT made of polysilicon and a TFT made of oxide semiconductor, a proposal is made to provide, as a portion of a peripheral circuit, a complementary metal oxide semiconductor (CMOS) circuit including a combination of a P-channel TFT formed of polysilicon semiconductor and an N-channel TFT formed of oxide semiconductor. However, the hybrid organic EL display device including the CMOS circuit undergoes complex production steps. At the production steps, discharge of accumulated static electricity might break an insulating film and water might enter from, for example, an organic resin material. As a result, for example, the TFTs included in the CMOS circuit would suffer deterioration in characteristics, which makes it difficult to ensure high yields. Such a hybrid organic EL display device has room for improvement.

The disclosure is conceived in view of the above problem, and sets out to reduce deterioration in characteristics of thin-film transistors included in a peripheral circuit included in a hybrid display device.

### Solution to Problem

In order to achieve the above object, a display device according to the disclosure includes: a base substrate; a thin-film transistor layer provided on the base substrate and including a first thin-film transistor having a first semiconductor layer formed of polysilicon and a second thin-film transistor having a second semiconductor layer formed of oxide semiconductor; a display region that displays an image, and a picture-frame region defined around the display region; a plurality of pixel thin-film transistors provided to each of a plurality of subpixels included in the display region, the plurality of pixel thin-film transistors serving as the first thin-film transistor and the second thin-film transistor; and a complementary metal oxide semiconductor circuit included in the picture-frame region and provided to serve as a portion of a drive circuit, the complementary metal oxide semiconductor circuit being a combination of the first thin-film transistor and the second thin-film transistor. The complementary metal oxide semiconductor circuit includes, in a plan view, at least one of a first protective pattern formed of the oxide semiconductor around the first semiconductor layer of the first thin-film transistor in the complementary metal oxide semiconductor circuit or a second protective pattern formed of the polysilicon around the second semiconductor layer of the second thin-film transistor in the complementary metal oxide semiconductor circuit.

### Advantageous Effect of Disclosure

The disclosure is directed to a hybrid display device and successfully reduces deterioration in characteristics of thin-film transistors included in a peripheral circuit.

### BRIEF DESCRIPTION OF DRAWINGS

FIG. 1 is a plan view of a schematic configuration of an organic EL display device according to a first embodiment of the disclosure.

FIG. 2 is a plan view of a display region of the organic EL display device according to the first embodiment of the disclosure.

FIG. 3 is a cross-sectional view of the display region of the organic EL display device according to the first embodiment of the disclosure.

FIG. 4 is an equivalent circuit diagram of a TFT layer included in the organic EL display device according to the first embodiment of the disclosure.

FIG. 5 is a cross-sectional view of an organic EL layer included in the organic EL display device according to the first embodiment of the disclosure.

FIG. 6 is an equivalent circuit diagram of a drive circuit including a complementary metal oxide semiconductor circuit of the organic EL display device according to the first embodiment of the disclosure.

FIG. 7 is a cross-sectional view of the complementary metal oxide semiconductor circuit included in the organic EL display device according to the first embodiment of the disclosure.

FIG. 8 is a plan view of a first TFT included in the complementary metal oxide semiconductor circuit of the organic EL display device according to the first embodiment of the disclosure.

FIG. 9 is a plan view of a second TFT included in the complementary metal oxide semiconductor circuit of the organic EL display device according to the first embodiment of the disclosure.

FIG. 10 is a plan view of a first modification of the first TFT included in the complementary metal oxide semiconductor circuit of the organic EL display device according to the first embodiment of the disclosure. FIG. 10 corresponds to FIG. 8.

FIG. 11 is a plan view of a second modification of the first TFT included in the complementary metal oxide semiconductor circuit of the organic EL display device according to the first embodiment of the disclosure. FIG. 11 corresponds to FIG. 8.

FIG. 12 is a plan view of a third modification of the first TFT included in the complementary metal oxide semiconductor circuit of the organic EL display device according to the first embodiment of the disclosure. FIG. 12 corresponds to FIG. 8.

FIG. 13 is a plan view of a fourth modification of the first TFT included in the complementary metal oxide semiconductor circuit of the organic EL display device according to the first embodiment of the disclosure. FIG. 13 corresponds to FIG. 8.

FIG. 14 is a plan view of a first modification of the second TFT included in the complementary metal oxide semiconductor circuit of the organic EL display device according to the first embodiment of the disclosure. FIG. 14 corresponds to FIG. 9.

FIG. 15 is a plan view of a second modification of the second TFT included in the complementary metal oxide semiconductor circuit of the organic EL display device according to the first embodiment of the disclosure. FIG. 14 corresponds to FIG. 9.

FIG. 16 is a plan view of a third modification of the second TFT included in the complementary metal oxide semiconductor circuit of the organic EL display device according to the first embodiment of the disclosure. FIG. 16 corresponds to FIG. 9.

FIG. 17 is a plan view of a fourth modification of the second TFT included in the complementary metal oxide semiconductor circuit of the organic EL display device according to the first embodiment of the disclosure. FIG. 17 corresponds to FIG. 9.

### DESCRIPTION OF EMBODIMENTS

Embodiments of the disclosure will be described in detail below with reference to the drawings. Note that the disclosure shall not be limited to the embodiments below.

### First Embodiment

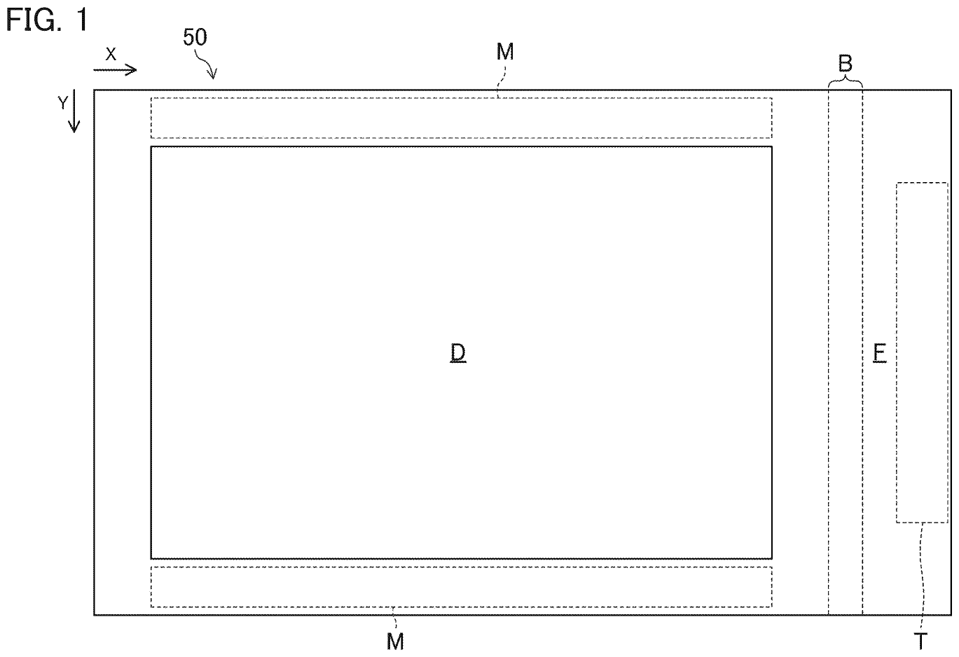

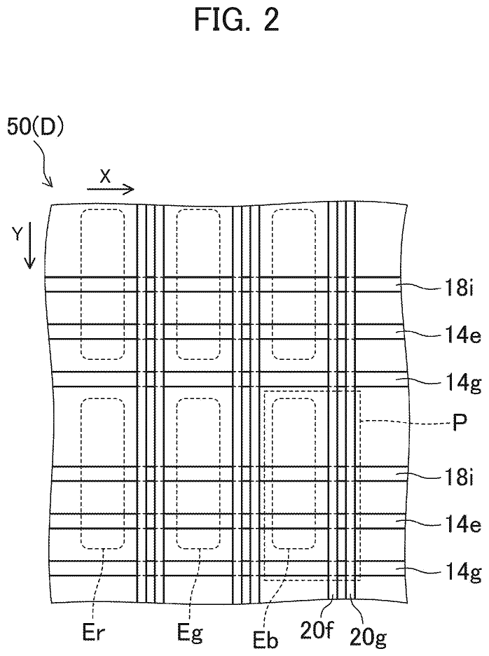

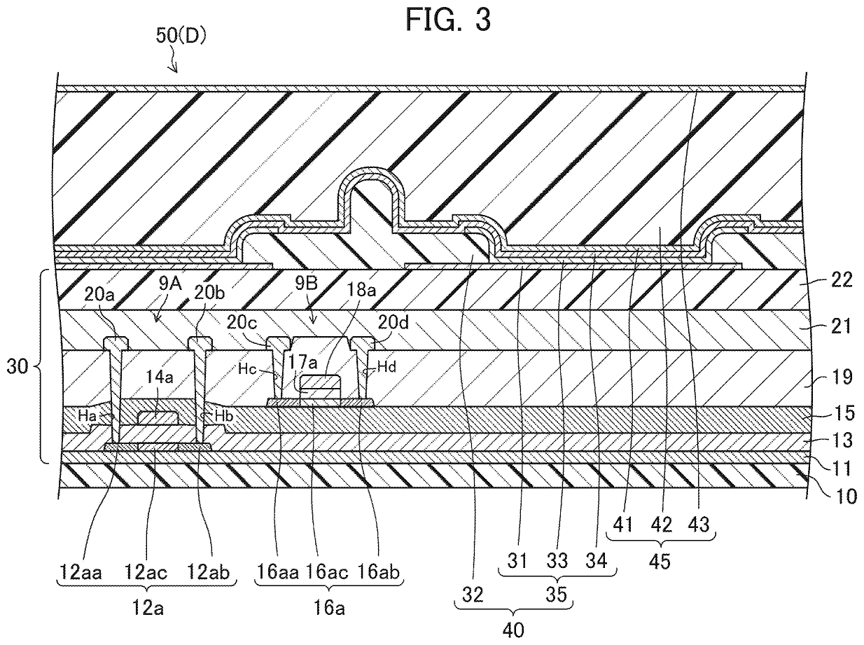

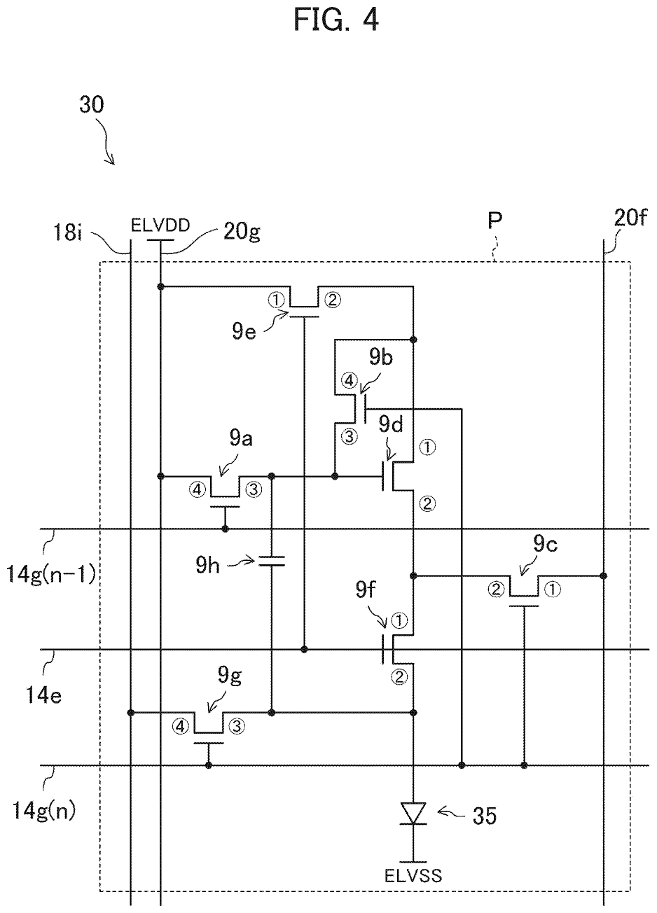

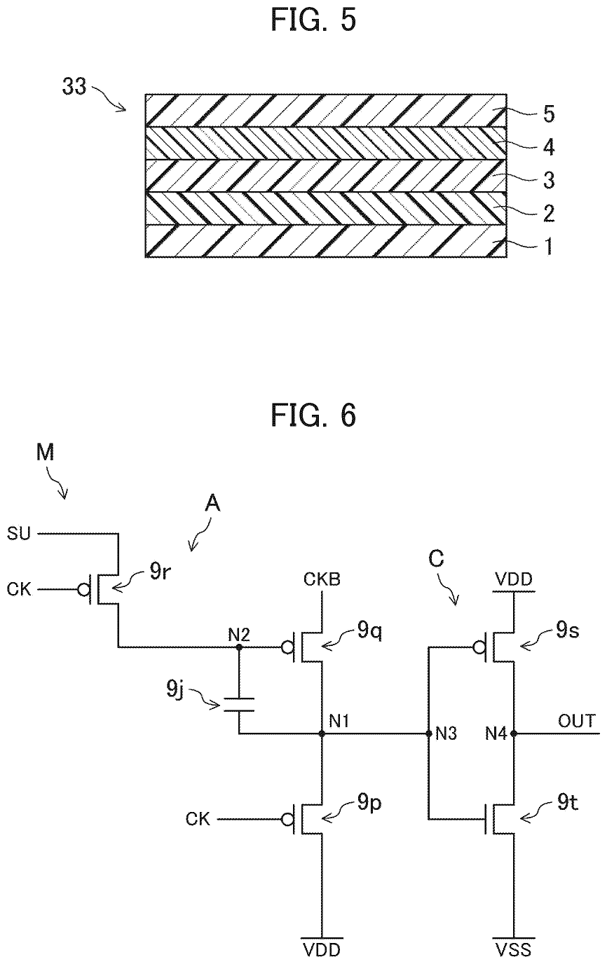

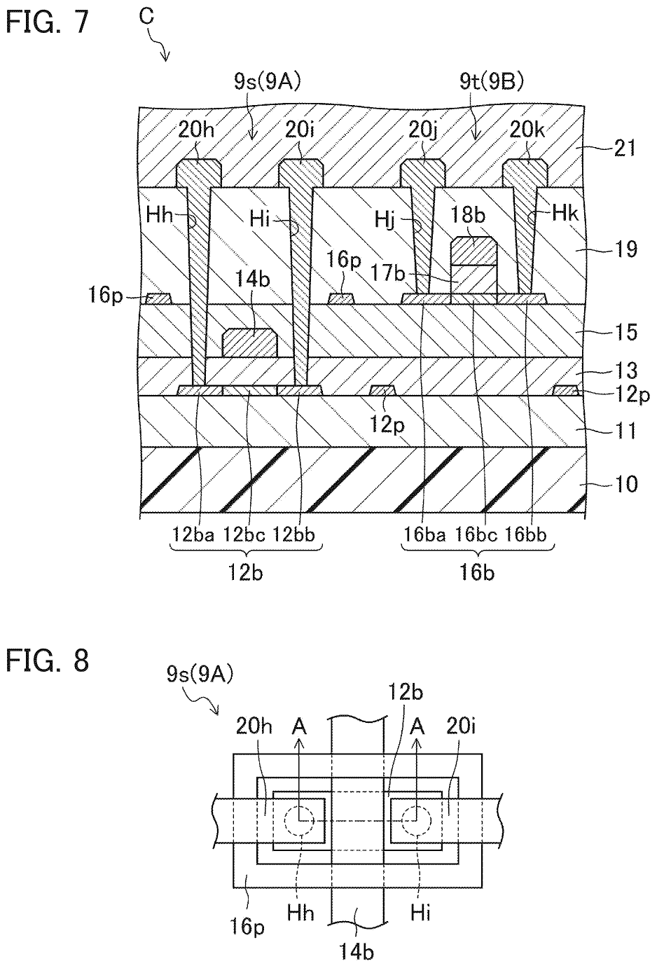

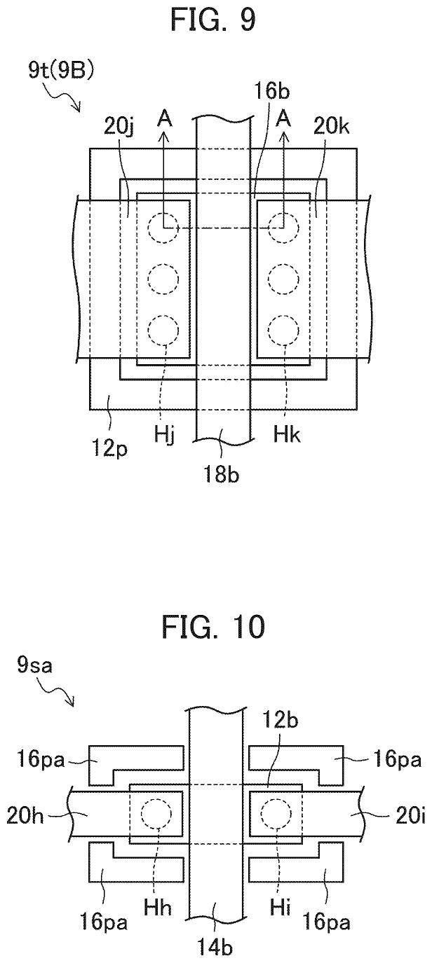

FIGS. 1 to 17 illustrate a first embodiment of a display device according to the disclosure. Note that, in the embodiments below, an organic EL display device including an organic-EL-element layer is exemplified as a display device including a light-emitting-element layer. Here, FIG. 1 is a plan view of a schematic configuration of an organic EL display device 50 according to this embodiment. FIG. 2 and FIG. 3 are respectively a plan view and a cross-sectional view of a display region D of the organic EL display device 50. FIG. 4 is an equivalent circuit diagram of the TFT layer 30 included in the organic EL display device 50. FIG. 5 is a cross-sectional view of an organic EL layer 33 included in the organic EL display device 50. FIG. 6 is an equivalent circuit diagram illustrating a gate driver circuit M including a CMOS circuit C of the organic EL display device 50. FIG. 7 is a cross-sectional view of the CMOS circuit C. FIGS. 8 and 9 are plan views of a fourth peripheral TFT 9s and a fifth peripheral TFT 9t both included in the CMOS circuit C. Note that cross-sectional views of the fourth peripheral TFT 9s and the fifth peripheral TFT 9t taken along line A-A in FIGS. 8 and 9 form a portion of the cross-sectional view in FIG. 7. Furthermore, FIGS. 10, 11, 12, and 13 are plan views of a first modification, a second modification, a third modification, and a fourth modification of the fourth peripheral TFT 9s included in the CMOS circuit C. Moreover, FIGS. 14, 15, 16, and 17 are plan views of a first modification, a second modification, a third modification, and a fourth modification of the fifth peripheral TFT 9t included in the CMOS circuit C.

As illustrated in FIG. 1, the organic EL display device 50 includes, for example: the display region D shaped into a rectangle and displaying an image; and a picture-frame region F shaped into a picture-frame shape and provided around the display region D. Note that this embodiment exemplifies the display region D shaped into a rectangle. Examples of the rectangle include such substantial rectangles as a rectangle having arc-like sides, a rectangle having rounded corners, and a rectangle having partially notched sides.

The display region D illustrated in FIG. 2 includes a plurality of subpixels P arranged in a matrix. Moreover, in the display region D, as illustrated in FIG. 2, for example, subpixels P having red light-emitting regions Er for presenting red, subpixels P having green light-emitting regions Eg for presenting green, and subpixels P having blue light-emitting regions Eb for presenting blue are provided side by side. Note that, in the display region D, for example, neighboring three subpixels P each having one of a red light-emitting region Er, a green light-emitting region Eg, and a blue light-emitting region Eb constitute one pixel.

The picture-frame region F in FIG. 1 has a right end portion provided with a terminal unit T extending in one direction (in a Y-direction in the drawing). Moreover, as illustrated in FIG. 1, the picture-frame region F includes, for example, a folding portion B between the display region D and the terminal unit T. The folding portion B, provided to the terminal unit T toward the display region D and extending in one direction (in the Y-direction in the drawing), is foldable around a folding axis in the Y-direction in the drawing at an angle of 180° (foldable in a U-shape). Furthermore, the picture-frame region F in FIG. 1 has an upper end portion and a lower end portion each provided with a gate driver circuit M to serve as a drive circuit. Note that, as will described later, the picture-frame region F includes a CMOS circuit C serving as a portion of the gate driver circuit M. The CMOS circuit C is a combination of the fourth peripheral TFT 9s and the fifth peripheral TFT 9t.

As illustrated in FIG. 3, the organic EL display device 50 includes: a resin substrate 10 provided as a base substrate; a TFT layer 30 provided on the resin substrate 10; an organic-EL-element layer 40 provided on the TFT layer 30 to serve as a light-emitting-element layer; and a sealing film 45 provided on the organic-EL-element layer 40.

The resin substrate 10 is made of, for example, an organic resin material such as polyimide resin.

The TFT layer 30 illustrated in FIG. 3 includes, in the display region D: a base coat film 11 provided on the resin substrate 10; four first TFTs 9A, three second TFTs 9B, and one capacitor 9h all of which are provided on the base coat film 11 for each of the subpixels P (see FIG. 4); and a protective insulating film 21 and a planarization film 22 sequentially provided above each of the first TFTs 9A, the second TFTs 9B, and the capacitor 9h. Here, the display region D of the TFT layer 30 includes, as illustrated in FIG. 2, a plurality of gate lines 14g extending in parallel with one another in an X-direction in the drawing. Furthermore, the display region D of the TFT layer 30 includes, as illustrated in FIG. 2, a plurality of light-emission control lines 14e extending in parallel with one another in the X-direction in the drawing. Moreover, the display region D of the TFT layer 30 includes, as illustrated in FIG. 2, a plurality of second initialization power supply lines 18i extending in parallel with one another in the X-direction in the drawing. Note that, as illustrated in FIG. 2, the light-emission control lines 14e are provided side by side with the gate lines 14g and the second initialization power supply lines 18i. Furthermore, the display region D of the TFT layer 30 includes, as illustrated in FIG. 2, a plurality of source lines 20f extending in parallel with one another in the Y-direction in the drawing. Furthermore, the display region D of the TFT layer 30 includes, as illustrated in FIG. 2, a plurality of power supply lines 20g extending in parallel with one another in the Y-direction in the drawing. Note that, as illustrated in FIG. 2, the power supply lines 20g and the source lines 20f are provided side by side.

The TFT layer 30 illustrated in FIG. 3 includes: the base coat film 11; a first semiconductor film; a first gate insulating film 13; a first metal film; a first interlayer insulating film 15; a second semiconductor film; a second gate insulating film 17a (17b in FIG. 7); a second metal film; a second interlayer insulating film 19; a third metal film; the protective insulating film 21; and the planarization film 22, all of which are sequentially stacked on top of another above the resin substrate 10. Here, the gate lines 14g and the light-emission control lines 14e are formed of the first metal film. Furthermore, the second initialization power supply lines 18i are formed of the second metal film. Moreover, the source lines 20f and the power supply lines 20g are formed of the third metal film.

Each of the base coat film 11, the first gate insulating film 13, the first interlayer insulating film 15, the second gate insulating film 17a (17b), the second interlayer insulating film 19, and the protective insulating film 21 is a monolayer inorganic insulating film made of such a substance as, for example, silicon nitride, silicon oxide, or silicon oxynitride. Alternatively, each film is a multilayer inorganic insulating film made of these substances. Here, the first interlayer insulating film 15 and the second gate insulating film 17a (17b) have respective portions toward the second semiconductor layer 16a (16b), and at least the portions are made of, for example, silicon oxide films. Note that the first gate insulating film 13, the first interlayer insulating film 15, the second gate insulating film 17a (17b), and the second interlayer insulating film 19 are respectively provided to serve as a first inorganic insulating film, a second inorganic insulating film, a third inorganic insulating film, and a fourth inorganic insulating film.

As illustrated in FIG. 3, each of the first TFTs 9A in the subpixel P includes: a first semiconductor layer 12a provided on the base coat film 11; a first gate electrode 14a provided above the first semiconductor layer 12a through the first gate insulating film 13; and a first terminal electrode 20a and a second terminal electrode 20b provided on the second interlayer insulating film 19 and spaced apart from each other.

The first semiconductor layer 12a is formed of the first semiconductor film made of, for example, polysilicon such as low-temperature polysilicon (LTPS). As illustrated in FIG. 3, the first semiconductor layer 12a includes: a first conductor region 12aa and a second conductor region 12ab defined to be spaced apart from each other; and a first channel region 12ac defined between the first conductor region 12aa and the second conductor region 12ab.

The first gate electrode 14a is formed of the first metal film. As illustrated in FIG. 3, the first gate electrode 14a is provided to overlap with the first channel region 12ac of the first semiconductor layer 12a. The first gate electrode 14a controls conduction between the first conductor region 12aa and the second conductor region 12ab of the first semiconductor layer 12a.

The first terminal electrode 20a and the second terminal electrode 20b are formed of the third metal film. As illustrated in FIG. 3, the first terminal electrode 20a and the second terminal electrode 20b are respectively and electrically connected to the first conductor region 12aa and the second conductor region 12ab of the first semiconductor layer 12a through a first contact hole Ha and a second contact hole Hb formed in a multilayer film including the first gate insulating film 13, the first interlayer insulating film 15, and the second interlayer insulating film 19.

As illustrated in FIG. 3, each of the second TFTs 9B in the subpixel P includes: a second semiconductor layer 16a provided on the first interlayer insulating film 15; a second gate electrode 18a provided above the second semiconductor layer 16a through the second gate insulating film 17a; and a third terminal electrode 20c and a fourth terminal electrode 20d provided on the second interlayer insulating film 19 and spaced apart from each other.

The second semiconductor layer 16a is formed of the second semiconductor film made of, for example, an In—Ga—Zn—O-based oxide semiconductor. As illustrated in FIG. 3, the second semiconductor layer 16a includes: a third conductor region 16aa and a fourth conductor region 16ab defined to be spaced apart from each other; and a second channel region 16ac defined between the third conductor region 16aa and the fourth conductor region 16ab. Here, the In—Ga—Zn—O-based oxide semiconductor is a ternary oxide of indium (In), gallium (Ga), and zinc (Zn), and a ratio (a composition ratio) of In to Ga to Zn is not limited to a particular ratio. Furthermore, the In—Ga—Zn—O-based oxide semiconductor may be amorphous or crystalline. Note that the crystalline In—Ga—Zn—O-based oxide semiconductor is preferably a crystalline In—Ga—Zn—O-based semiconductor in which the c-axis is oriented substantially perpendicular to the layer plane. Moreover, instead of the In—Ga—Zn—O-based semiconductor, the second semiconductor layer 16a may contain another oxide semiconductor. Examples of the other oxide semiconductor may include an In—Sn—Zn—O-based semiconductor (e.g., In₂O₃—SnO₂—ZnO; InSnZnO). Here, the In—Sn—Zn—O-based semiconductor is a ternary oxide of indium (In), tin (Sn), and zinc (Zn). In addition, other oxide semiconductors may include: an In—Al—Zn—O-based semiconductor; an In—Al—Sn—Zn—O-based semiconductor; a Zn—O-based semiconductor; an In—Zn—O-based semiconductor; a Zn—Ti—O-based semiconductor; a Cd—Ge—O-based semiconductor; a Cd—Pb—O-based semiconductor; cadmium oxide (CdO); a Mg—Zn—O-based semiconductor; an In—Ga—Sn—O-based semiconductor; an In—Ga—O-based semiconductor; a Zr—In—Zn—O-based semiconductor; a Hf—In—Zn—O-based semiconductor; an Al—Ga—Zn—O-based semiconductor; a Ga—Zn—O-based semiconductor; an In-Ga—Zn—Sn—O-based semiconductor; InGaO₃(ZnO)₅; zinc magnesium oxide (MgₓZn₁₋ₓO), and zinc cadmium oxide (CdₓZn₁₋ₓO). Note that the Zn—O-based semiconductor may be ZnO doped with one or more kinds of impurity elements among a group 1 element, a group 13 element, a group 14 element, a group 15 element, and a group 17 element. The Zn—O-based semiconductor may be in an amorphous state, in a polycrystalline state, or in a microcrystalline state in which an amorphous state and a polycrystalline state are mixed together. Alternatively. the Zn—O-based semiconductor does not have to be doped with any impurity element.

The second gate electrode 18a is formed of the second metal film. As illustrated in FIG. 3, the second gate electrode 18a is provided to overlap with the second channel region 16ac of the second semiconductor layer 16a. The second gate electrode 18a controls conduction between the third conductor region 16aa and the fourth conductor region 16ab of the second semiconductor layer 16a. Here, as illustrated in FIG. 3, the second gate insulating film 17a below the second gate electrode 18a is shaped into an island shape, and provided to overlap with the second gate electrode 18a.

The third terminal electrode 20c and the fourth terminal electrode 20d are formed of the third metal film. As illustrated in FIG. 3, the third terminal electrode 20c and the fourth terminal electrode 20d are respectively and electrically connected to the third conductor region 16aa and the fourth conductor region 16ab of the second semiconductor layer 16a through a third contact hole Hc and a fourth contact hole Hd formed in the second interlayer insulating film 19.

In this embodiment, a write TFT 9c, a drive TFT 9d, a power-supply TFT 9e, and a light-emission control TFT 9f to be described later are exemplified as the four first TFTs 9A each having the first semiconductor layer 12a formed of polysilicon, and an initialization TFT 9a, a compensation TFT 9b, and an anode-discharge TFT 9g to be described later are exemplified as the three second TFTs 9B each having the second semiconductor layer 16a formed of oxide semiconductor (see FIG. 4). Note that, in the equivalent circuit diagram in FIG. 4, the first terminal electrode 20a and the second terminal electrode 20b of each of the TFTs 9c, 9d, 9e, and 9f are denoted by circled numerals 1 and 2, and the third terminal electrode 20c and the fourth terminal electrode 20d of each of the TFTs 9a, 9b, and 9g are denoted by circled numerals 3 and 4. Furthermore, the equivalent circuit diagram in FIG. 4 illustrates a pixel circuit of a subpixel P at the n-th row and the m-th column. The equivalent circuit diagram also partially includes a pixel circuit of a subpixel P at the (n-1)-th row and the m-th column. In addition, in the equivalent circuit diagram in FIG. 4, the power supply line 20g to supply a high power-supply voltage ELVDD also serves as a first initialization power supply line; however, the power supply line 20g and the first initialization power supply line may be provided separately. Moreover, the second initialization power supply line 18i receives, but not limited to, the same voltage as a low power-supply voltage ELVSS. The second initialization power supply line 18i may receive a voltage that differs from the low power-supply voltage ELVSS, and that turns OFF an organic EL element 35 to be described later.

As illustrated in FIG. 4, in each subpixel P, the initialization TFT 9a has: a gate electrode electrically connected to a gate line 14g(n-1) in a preceding stage (n-1 stage); the third terminal electrode electrically connected to a lower conductive layer of the capacitor 9h and to a gate electrode of the drive TFT 9d; and the fourth terminal electrode electrically connected to the power supply line 20g.

As illustrated in FIG. 4, in each subpixel P, the compensation TFT 9b has: a gate electrode electrically connected to a gate line 14g(n) in a corresponding stage (n-th stage); the third terminal electrode electrically connected to the gate electrode of the drive TFT 9d; and the fourth terminal electrode electrically connected to the first terminal electrode of the drive TFT 9d.

As illustrated in FIG. 4, in each subpixel P, the write TFT 9c has: a gate electrode electrically connected to the gate line 14g(n) in the corresponding stage (n-th stage); the first terminal electrode electrically connected to a corresponding source line 20f; and the second terminal electrode electrically connected to the second terminal electrode of the drive TFT 9d.

As illustrated in FIG. 4, in each subpixel P, the drive TFT 9d has: the gate electrode electrically connected to the third terminal electrode of each of the initialization TFT 9a and the compensation TFT 9b; the first terminal electrode electrically connected to the fourth terminal electrode of the compensation TFT 9b and to the second terminal electrode of the power-supply TFT 9e; and the second terminal electrode electrically connected to the second terminal electrode of the write TFT 9c and to the first terminal electrode of the light-emission control TFT 9f. Here, the drive TFT 9d controls a drive current of the organic EL element 35.

As illustrated in FIG. 4, in each subpixel P, the power-supply TFT 9e has: a gate electrode electrically connected to a light-emission control line 14e in the corresponding stage (n-th stage); the first terminal electrode electrically connected to the power supply line 20g; and the second terminal electrode electrically connected to the first terminal electrode of the drive TFT 9d.

As illustrated in FIG. 4, in each subpixel P, the light-emission control TFT 9f has: a gate electrode electrically connected to the light-emission control line 14e in the corresponding stage (n-th stage); the first terminal electrode electrically connected to the second terminal electrode of the drive TFT 9d; and the second terminal electrode electrically connected to a first electrode 31 of the organic EL element 35. The first electrode 31 and the organic EL element 35 will be described later.

As illustrated in FIG. 4, in each subpixel P, the anode-discharge TFT 9g has: a gate electrode electrically connected to the gate line 14g(n) in the corresponding stage (n-th stage); the third terminal electrode electrically connected to the first electrode 31 of the organic EL element 35; and the fourth terminal electrode electrically connected to a second initialization power supply line 18i.

The capacitor 9h includes, for example: a lower conductive layer (not shown) formed of the first metal film; the first interlayer insulating film 15 and a second gate insulating film (not shown) provided to cover the lower conductive layer; and an upper conductive layer (not shown) formed of the second metal film and provided on the second gate insulating film to overlap with the lower conductive layer. Moreover, as illustrated in FIG. 4, in each subpixel P, the capacitor 9h has: the lower conductive layer electrically connected to the gate electrode of the drive TFT 9d and to the third terminal electrode of each of the initialization TFT 9a and the compensation TFT 9b; and the upper conductive layer electrically connected to the third terminal electrode of the anode-discharge TFT 9g, to the second terminal electrode of the light-emission control TFT 9f, and to the first electrode 31 of the organic EL element 35.

The planarization film 22 has a flat surface in the display region D. The planarization film 22 is made of, for example, an organic resin material such as polyimide resin.

As illustrated in FIG. 3, the organic-EL-element layer 40 includes a plurality of organic EL elements 35. The organic EL elements 35, serving as a plurality of light-emitting elements, are arranged on the TFT layer 30 in a matrix, so as to correspond to the plurality of respective subpixels P. Here, as illustrated in FIG. 3, each of the organic EL elements 35 includes: a first electrode 31 provided on the TFT layer 30; an organic EL layer 33 provided on the first electrode 31; and a second electrode 34 provided on the organic EL layer 33 in common with the entire display region D.

The first electrode 31 is electrically connected through a contact hole formed in a multilayer film including the protective insulating film 21 and the planarization film 22 to the second terminal electrode of the light-emission control TFT 9f for each subpixel P. Furthermore, the first electrode 31 has a function of injecting holes into the organic EL layer 33. Moreover, the first electrode 31 is preferably formed of a material having a large work function to improve efficiency in injecting the holes into the organic EL layer 33. Here, examples of the material forming the first electrode 31 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). In addition, the first electrode 31 may be made of, for example, an alloy of astatine (At)/astatine oxide (AtO₂). Furthermore, the first electrode 31 may be made of a conductive oxide such as, for example, tin oxide (SnO), zinc oxide (ZnO), indium tin oxide (ITO), or indium zinc oxide (IZO). Moreover, the first electrode 31 may be formed of a plurality of layers made of the above materials and stacked on top of another. Note that examples of compound materials having a large work function include indium tin oxide (ITO) and indium zinc oxide (IZO). In addition, the first electrode 31 has a peripheral end portion covered with an edge cover 32 provided in a grid pattern throughout the display region D. Here, the edge cover 32 is made of, for example, an organic resin material such as polyimide resin or acrylic resin, or a polysiloxane-based spin-on-glass (SOG) material.

As illustrated in FIG. 5, the organic EL layer 33 includes: a hole injection layer 1; a hole transport layer 2; a light-emitting layer 3; an electron transport layer 4; and an electron injection layer 5, all of which are sequentially stacked above the first electrode 31.

The hole injection layer 1 is also referred to as an anode buffer layer. The hole injection layer 1 has a function of approximating energy levels between the first electrode 31 and the organic EL layer 33 to improve efficiency in injecting the holes from the first electrode 31 into the organic EL layer 33. Here, examples of a material forming the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has a function of improving efficiency in transporting the holes from the first electrode 31 to the organic EL layer 33. Here, examples of a material forming the hole transport layer 2 include a porphyrin derivative, an aromatic tertiary amine compound, a styrylamine derivative, polyvinyl carbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, zinc selenide, and zinc selenide.

The light-emitting layer 3 is a region where the holes and the electrons are respectively injected from the first electrode 31 and the second electrode 34, and recombine together, when a voltage is applied with the first electrode 31 and the second electrode 34. Here, the light-emitting layer 3 is formed of a material having high light-emission efficiency. Examples of the material forming the light-emitting layer 3 include a metal oxinoid compound [8-hydroxyquinoline metal complex], a naphthalene derivative, an anthracene derivative, a diphenylethylene derivative, a vinylacetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrylbenzene derivative, a perylene derivative, a perinone derivative, an aminopyrene derivative, a pyridine derivative, a rhodamine derivative, an aquizine derivative, phenoxazone, a quinacridone derivative, rubrene, poly-p-phenylenevinylene, and polysilane.

The electron transport layer 4 has a function of efficiently moving the electrons to the light-emitting layer 3. Here, examples of a material forming the electron transport layer 4 include, as organic compounds, an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has a function of approximating energy levels between the second electrode 34 and the organic EL layer 33 to improve efficiency in injecting the electrons from the second electrode 34 into the organic EL layer 33. Such a function can decrease a drive voltage of the organic EL element 35. Note that the electron injection layer 5 is also referred to as a cathode buffer layer. Here, examples of a material forming the electron injection layer 5 include: inorganic alkali compounds such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 3, the second electrode 34 is provided to cover each organic EL layer 33 and the edge cover 32. Moreover, the second electrode 34 has a function of injecting the electrons into the organic EL layer 33. Furthermore, the second electrode 34 is preferably formed of a material having a small work function to improve efficiency in injecting the electrons into the organic EL layer 33. Here, examples of the material forming the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Moreover, the second electrode 34 may be formed of an alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), or lithium fluoride (LiF)/calcium (Ca)/aluminum (Al). Furthermore, the second electrode 34 may be formed of a conductive oxide such as tin oxide (SnO), zinc oxide (ZnO), indium tin oxide (ITO), or indium zinc oxide (IZO). In addition, the second electrode 34 may be formed of a plurality of layers made of the above materials and stacked on top of another. Note that examples of the material having a small work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As illustrated in FIG. 3, the sealing film 45 is provided to cover the second electrode 34, and includes: a first inorganic sealing film 41; an organic sealing film 42; and a second inorganic sealing film 43, all of which are sequentially stacked on top of another above the second electrode 34. The sealing film 45 has a function of protecting the organic EL layers 33 in the organic EL element 35 from moisture and oxygen. Here, each of the first inorganic sealing film 41 and the second inorganic sealing film 43 is formed of such an inorganic insulating film as, for example, a silicon nitride film, a silicon oxide film, or a silicon oxynitride film. Moreover, the organic sealing film 42 is formed of such an organic resin material as, for example, acrylic resin, epoxy resin, silicone resin, polyurea resin, parylene resin, polyimide resin, or polyamide resin.

Furthermore, as illustrated in FIG. 7, the organic EL display device 50 (the TFT layer 30) includes, in the picture-frame region F: the base coat film 11 provided on the resin substrate 10; four first TFTs 9A, one second TFT 9B, and one capacitor 9j all of which are provided on the base coat film 11 to serve as the gate driver circuit M (see FIG. 6); and the protective insulating film 21 and the planarization film 22 sequentially provided above each of the first TFTs 9A, the second TFT 9B, and the capacitor 9j.

As illustrated in FIGS. 7 and 8, each first TFT 9A in the picture-frame region F includes: a first semiconductor layer 12b provided on the base coat film 11; a first gate electrode 14b provided above the first semiconductor layer 12b through the first gate insulating film 13; a first source electrode 20h and a first drain electrode 20i provided on the second interlayer insulating film 19 and spaced apart from each other; and a first protective pattern 16p provided around the first semiconductor layer 12b in a plan view.

Similar to the first semiconductor layer 12a, the first semiconductor layer 12b is formed of the first semiconductor film. As illustrated in FIG. 7, the first semiconductor layer 12b includes: a first source region 12ba and a first drain region 12bb defined to be spaced apart from each other; and a first channel region 12bc defined between the first source region 12ba and the first drain region 12bb.

Similar to the first gate electrode 14a, the first gate electrode 14b is formed of the first metal film. As illustrated in FIG. 7, the first gate electrode 14b is provided to overlap with the first channel region 12bc of the first semiconductor layer 12b. The first gate electrode 14b controls conduction between the first source region 12ba and the first drain region 12bb of the first semiconductor layer 12b.

The first source electrode 20h and the first drain electrode 20i are formed of the third metal film. As illustrated in FIG. 7, the first source electrode 20h and the first drain electrode 20i are respectively and electrically connected to the first source region 12ba and the first drain region 12bb of the first semiconductor layer 12b through a first contact hole Hh and a second contact hole Hi formed in a multilayer film including the first gate insulating film 13, the first interlayer insulating film 15, and the second interlayer insulating film 19.

Similar to the second semiconductor layer 16a, the first protective pattern 16p is formed of the (conductive) second semiconductor film. As illustrated in FIG. 8, the first protective pattern 16p is shaped into a rectangular picture-frame-shaped loop to surround the first semiconductor layer 12b in a plan view.

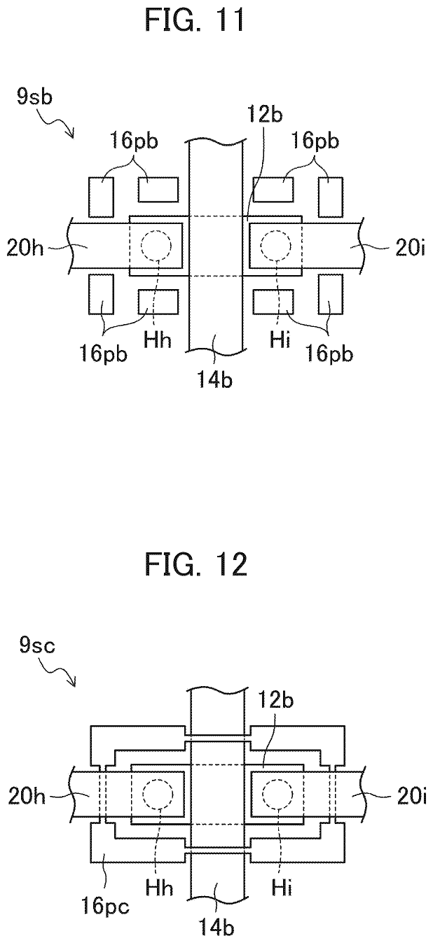

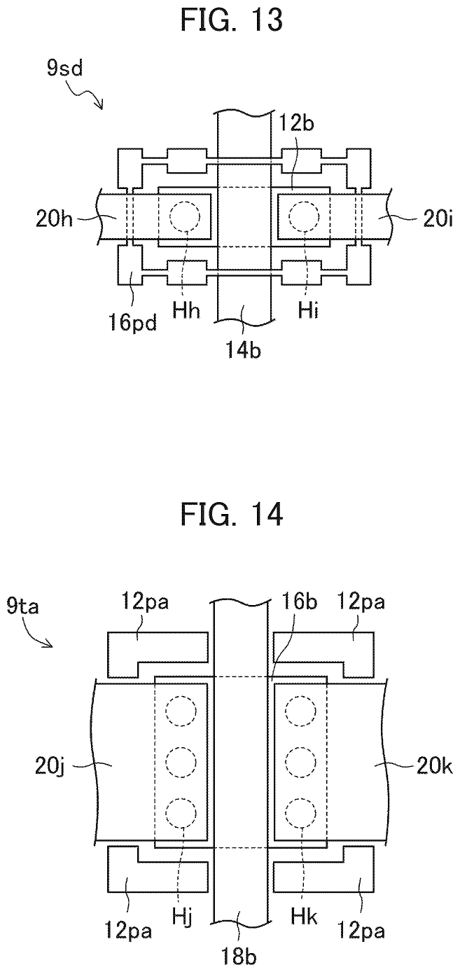

Note that this embodiment exemplifies the first TFT 9A (i.e., the fourth peripheral TFT 9s to be described later) including the first protective pattern 16p shaped into a loop having an equal line width. Alternatively, the fourth peripheral TFT 9s may be, for example, a fourth peripheral TFT 9sa including a first protective pattern 16pa as illustrated in FIG. 10, a fourth peripheral TFT 9sb including a first protective pattern 16pb as illustrated in FIG. 11, a fourth peripheral TFT 9sc including a first protective pattern 16pc as illustrated in FIG. 12, and a fourth peripheral TFT 9sd including a first protective pattern 16pd as illustrated in FIG. 13.

As illustrated in FIG. 10, the fourth peripheral TFT 9sa includes four first protective patterns 16pa surrounding the first semiconductor layer 12b in a plan view and each shaped into an island shape not to overlap with wires each connected to one of the first gate electrode 14b, the first source electrode 20h, and the first drain electrode 20i.

As illustrated in FIG. 11, the fourth peripheral TFT 9sb includes eight first protective patterns 16pb surrounding the first semiconductor layer 12b in a plan view and each shaped into an island shape not to overlap with wires each connected to one of the first gate electrode 14b, the first source electrode 20h, and the first drain electrode 20i.

As illustrated in FIG. 12, the fourth peripheral TFT 9sc includes the first protective pattern 16pc: shaped into a loop to surround the first semiconductor layer 12b in a plan view; and having a portion not overlapping with wires each connected to one of the first gate electrode 14b, the first source electrode 20h, and the first drain electrode 20i and a portion overlapping with the wires and shaped narrower than the portion not overlapping with the wires. Specifically, the first protective pattern 16pc includes the four first protective patterns 16pa connected together (see FIG. 10).

As illustrated in FIG. 13, the fourth peripheral TFT 9sd includes the first protective pattern 16pd: shaped into a loop to surround the first semiconductor layer 12b in a plan view; and having a portion not overlapping with wires each connected to one of the first gate electrode 14b, the first source electrode 20h, and the first drain electrode 20i and a portion overlapping with the wires and shaped narrower than the portion not overlapping with the wires. Specifically, the first protective pattern 16pc includes the eight first protective patterns 16pb connected together (see FIG. 11).

As illustrated in FIGS. 7 and 9, the second TFT 9B in the picture-frame region F includes: a second semiconductor layer 16b provided on the first interlayer insulating film 15; a second gate electrode 18b provided above the second semiconductor layer 16b through a second gate insulating film 17b; a second source electrode 20j and a second drain electrode 20k provided on the second interlayer insulating film 19 and spaced apart from each other; and a second protective pattern 12p provided around the second semiconductor layer 16b in a plan view.

Similar to the second semiconductor layer 16a, the second semiconductor layer 16b is formed of the second semiconductor film. As illustrated in FIG. 7, the second semiconductor layer 16b includes: a second source region 16ba and a second drain region 16bb defined to be spaced apart from each other; and a second channel region 16bc defined between the second source region 16ba and the second drain region 16bb.

Similar to the second gate electrode 18a, the second gate electrode 18b is formed of the second metal film. As illustrated in FIG. 7, the second gate electrode 18b is provided to overlap with the second channel region 16bc of the second semiconductor layer 16b. The second gate electrode 18b controls conduction between the second source region 16ba and the second drain region 16bb of the second semiconductor layer 16b. Here, as illustrated in FIG. 7, the second gate insulating film 17b below the second gate electrode 18b is shaped into an island shape and provided to overlap with the second gate electrode 18b.

The second source electrode 20j and the second drain electrode 20k are formed of the third metal film. As illustrated in FIG. 7, the second source electrode 20j and the second drain electrode 20k are respectively and electrically connected to the second source region 16ba and the second drain region 16bb of the second semiconductor layer 16b through a third contact hole Hj and a fourth contact hole Hk formed in the second interlayer insulating film 19.

Similar to the first semiconductor layer 12a, the second protective pattern 12p is formed of the (conductive) first semiconductor film. As illustrated in FIG. 9, the second protective pattern 12p is shaped into a rectangular picture-frame-shaped loop to surround the second semiconductor layer 16b in a plan view.

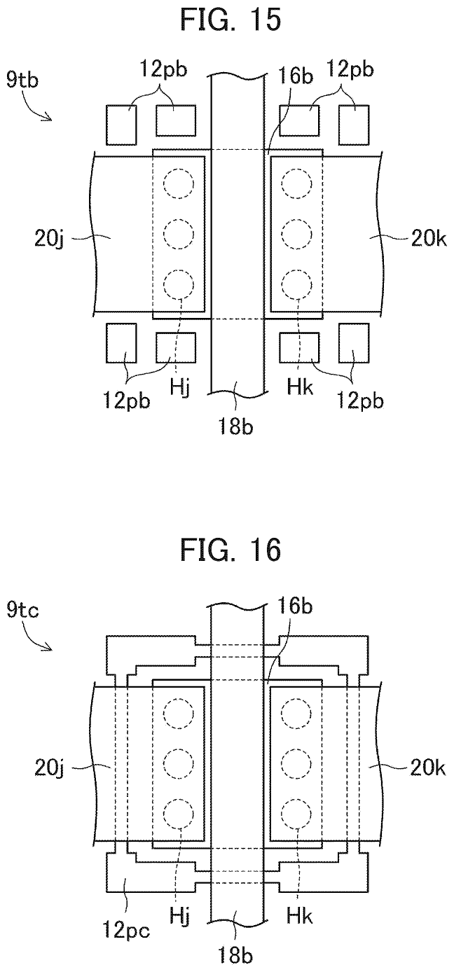

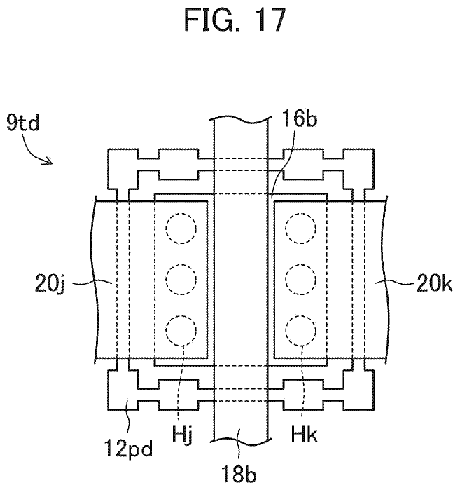

Note that this embodiment exemplifies the first TFT 9B (i.e., the fifth peripheral TFT 9t to be described later) including the second protective pattern 12p shaped into a loop having an equal line width. Alternatively, the fifth peripheral TFT 9t may be, for example, a fifth peripheral TFT 9ta including a second protective pattern 12pa as illustrated in FIG. 14, a fifth peripheral TFT 9tb including a second protective pattern 12pb as illustrated in FIG. 15, a fifth peripheral TFT 9tc including a second protective pattern 12pc as illustrated in FIG. 16, and a fifth peripheral TFT 9td including a second protective pattern 12pd as illustrated in FIG. 17. Here, the first protective patterns 16p (16pa, 16pb, 16pc, and 16pd) and the second protective patterns 12p (12pa, 12pb, 12pc, and 12pd) may make any given combinations.

As illustrated in FIG. 14, the fifth peripheral TFT 9ta includes four second protective patterns 12pa surrounding the second semiconductor layer 16b in a plan view and each shaped into an island shape not to overlap with wires each connected to one of the second gate electrode 18b, the second source electrode 20j, and the second drain electrode 20k.

As illustrated in FIG. 15, the fifth peripheral TFT 9tb includes eight second protective patterns 12pb surrounding the second semiconductor layer 16b in a plan view and each shaped into an island shape not to overlap with wires each connected to one of the second gate electrode 18b, the second source electrode 20j, and the second drain electrode 20k.

As illustrated in FIG. 16, the fifth peripheral TFT 9tc includes the second protective pattern 12pc: shaped into a loop to surround the second semiconductor layer 16b in a plan view; and having a portion not overlapping with wires each connected to one of the second gate electrode 18b, the second source electrode 20j, and the second drain electrode 20k and a portion overlapping with the wires and shaped narrower than the portion not overlapping with the wires. Specifically, the second protective pattern 12pc includes the four second protective patterns 12pa connected together (see FIG. 14).

As illustrated in FIG. 17, the fifth peripheral TFT 9td includes the second protective pattern 12pd: shaped into a loop to surround the second semiconductor layer 16b in a plan view; and having a portion not overlapping with wires each connected to one of the second gate electrode 18b, the second source electrode 20j, and the second drain electrode 20k and a portion overlapping with the wires and shaped narrower than the portion not overlapping with the wires. Specifically, the second protective pattern 12pd includes the eight second protective patterns 12pb connected together (see FIG. 15).

This embodiment exemplifies: a first peripheral TFT 9p, a second peripheral TFT 9q, a third peripheral TFT 9r, and a fourth peripheral TFT 9s to be described later as the four first TFTs 9A each having the first semiconductor layer 12b formed of polysilicon; and the fifth peripheral TFT 9t to be described later as the one second TFT 9B having the second semiconductor layer 16b formed of oxide semiconductor (see FIG. 6).

Here, as illustrated in FIG. 6, the gate driver circuit M includes: a flip-flop circuit A; and the CMOS circuit C, both of which are provided for each gate line 14g.

The flip-flop circuit A illustrated in FIG. 6 includes: the first peripheral TFT 9p; the second peripheral TFT 9q, and the third peripheral TFT 9r, all of which are provided as P-channel TFTs; and the one capacitor 9j. The flip-flop circuit A alternately receives a clock signal CK and an inverted clock signal CKB to output, to a node N1, a gate signal shifted by a half cycle from the clock signal CK.

The first peripheral TFT 9p illustrated in FIG. 6 has: a first gate electrode 14b receiving the clock signal; a first source electrode 20h electrically connected to a power supply line of a high level VDD; and a first drain electrode 20i electrically connected to the node N1. Note that the first peripheral TFT 9p may omit the first protective pattern 16p (see FIG. 7).

The second peripheral TFT 9q illustrated in FIG. 6 has: a first gate electrode 14b electrically connected to a node N2; a first source electrode 20h receiving the inverted clock signal CKB; and a first drain electrode 20i electrically connected to the node N1. Note that the second peripheral TFT 9q may omit the first protective pattern 16p (see FIG. 7).

The third peripheral TFT 9r illustrated in FIG. 6 has: a first gate electrode 14b receiving the clock signal; a first source electrode 20h receiving a start pulse SU; and a first drain electrode 20i electrically connected to the node N2. Note that the third peripheral TFT 9r may omit the first protective pattern 16p (see FIG. 7). Here, the start pulse SU is applied when the flip-flop circuit A is in the first stage. When the flip-flop circuit A is in the second stage succeeding the first state, the first source electrode 20h of the third peripheral TFT 9r receives the gate signal output in the first stage, instead of the start pulse SU. Hence, in a stage succeeding the second stage, the first source electrode 20h of the third peripheral TFT 9r in the flip-flop circuit A receives a gate signal of the preceding stage.

The capacitor 9j illustrated in FIG. 6 is connected between the node N1 and the node N2, and maintains a voltage between the first drain electrode 20i and the first gate electrode 14b of the second peripheral TFT 9q.

The CMOS circuit C illustrated in FIGS. 6 and 7 includes: the fourth peripheral TFT 9s provided as a P-channel TFT; and the fifth peripheral TFT 9t provided as an N-channel TFT. If the gate signal input from a node N3 has the same potential as that of a low-level voltage VSS, the fourth peripheral TFT 9s turns ON, the fifth peripheral TFT 9t turns OFF, and the same potential as that of a high-level voltage VDD is output from a node N4. If the gate signal input from the node N3 has the same potential as that of the high-level voltage VDD, the fourth peripheral TFT 9s turns OFF, the fifth peripheral TFT 9t turns ON, and the same potential as that of the low-level voltage VSS is output from the node N4. Note that the node N3 of the CMOS circuit C is electrically connected to the node N1 of the flip-flop circuit A.

The fourth peripheral TFT 9s illustrated in FIG. 6 has: a first gate electrode 14b electrically connected to the node N3; a first source electrode 20h electrically connected to a power supply line of the high-level voltage VDD; and a first drain electrode 20i electrically connected to the node N4. Note that, as described above, the fourth peripheral TFT 9s includes: the first semiconductor layer 12b, the first gate electrode 14b, the first source electrode 20h, the first drain electrode 20i, and the first protective pattern 16p (see FIG. 7).

The fifth peripheral TFT 9t illustrated in FIG. 6 has: a second gate electrode 18b electrically connected to the node N3; a second source electrode 20j electrically connected to a power supply line of the low-level voltage VSS; and a second drain electrode 20k electrically connected to the node N4. Note that, as described above, the fifth peripheral TFT 9t includes: the second semiconductor layer 16b, the second gate electrode 18b, the second source electrode 20j, the second drain electrode 20k, and the second protective pattern 12p (see FIG. 7).

Described here is an operation of the gate driver circuit M (the flip-flop circuit A and the CMOS circuit C).

As to the flip-flop circuit A, for example, when the clock signal CK is at the low level, the inverted clock signal CKB is at the high level, and the start pulse SU is at the low level, the first peripheral TFT 9p and the third peripheral TFT 9r turn ON. Here, the start pulse SU at the low level is input to the first gate electrode 14b of the second peripheral TFT 9q, and the second peripheral TFT 9q turns ON. Whereas, the inverted clock signal CKB at the high level is applied to the first source electrode 20h of the second peripheral TFT 9q, such that the second peripheral TFT 9q does not conduct a current. Hence, a gate signal at the high level is output to the node N1. Subsequently, the gate signal at the high level output from the node N1 is input to the node N3. Because the gate signal has the same potential as the potential of the high-level voltage VDD, the fourth peripheral TFT 9s turns OFF, the fifth peripheral TFT 9t turns ON, and the gate signal having the same potential as the potential of the low-level voltage VSS is output from the node N4.

Next, as to the flip-flop circuit A, for example, when the clock signal CK is at the high level, the inverted clock signal CKB is at the low level, and the start pulse SU is at the high level, the first peripheral TFT 9p and the third peripheral TFT 9r turn OFF. Here, the inverted clock signal CKB at the low level is input to the first source electrode 20h of the second peripheral TFT 9q, and the second peripheral TFT 9q turns ON. Then, a current flows through the second peripheral TFT 9q because of the high-level voltage stored in the node N1, and the voltage of the node N1 falls by the inverted clock signal CKB at the low level. This is because the node N2 connected to one of the terminals of the capacitor 9j is in a floating state since the third peripheral TFT 9r is OFF, and thus the voltage of the node N2 falls by the fall of the voltage of the node N1, thereby enabling full-down. Hence, a gate signal at the low level is output to the node N1. Subsequently, the gate signal at the low level output from the node N1 is input to the node N3. When the gate signal has the same potential as the potential of the low-level voltage VSS, the fourth peripheral TFT 9s turns ON, the fifth peripheral TFT 9t turns OFF, and the gate signal having the same potential as the potential of the high-level voltage VDD is output from the node N4.

As to the organic EL display device 50 having the above configuration, in each subpixel P, when the light-emission control line 14e is first selected to be in an inactive state, the organic EL element 35 is in a non-light-emission state. In the non-light-emission state, the gate line 14g(n-1) in the preceding stage is selected. Through the gate line 14g(n-1), a gate signal is input into the initialization TFT 9a such that the initialization TFT 9a turns ON. Hence, the high power-supply voltage ELVDD of the power supply line 20g is applied to the capacitor 9h, and the drive TFT 9d turns ON. Thus, charges of the capacitor 9h are discharged, and a voltage to be applied to the gate electrode of the drive TFT 9d is initialized. Next, when the gate line 14g(n) of the corresponding stage is selected to be in the active state, the compensation TFT 9b and the write TFT 9c turn ON, and a predetermined voltage corresponding to a source signal to be transmitted through the corresponding source line 20f is written into the capacitor 9h through the drive TFT 9d connected to a diode. Simultaneously, the anode-discharge TFT 9g turns ON, and an initialization signal is applied through the second initialization power supply line 18i to the first electrode 31 of the organic EL element 35. Hence, the charges stored in the first electrode 31 are reset. After that, the light-emission control line 14e is selected, and the power-supply TFT 9e and the light-emission control TFT 9f turn ON. Hence, a drive current corresponding to the voltage applied to the gate electrode of the drive TFT 9d is supplied from the power supply line 20g to the organic EL element 35. Thus, in each subpixel P, the organic EL element 35 emits light the luminance of which corresponds to the drive current. This is how the organic EL display device 50 displays an image.

Described next will be a method for producing the organic EL display device 50 of this embodiment. Here, the method for producing the organic EL display device 50 of this embodiment includes: a TFT-layer forming step; an organic-EL-element-layer forming step; and a sealing-film forming step.

### TFT-Layer Forming Step

First, a silicon nitride film (approximately 50 nm in thickness) and a silicon oxide film (approximately 250 nm in thickness) are sequentially deposited by, for example, plasma chemical vapor deposition (CVD) on the resin substrate 10 formed on a glass substrate. Hence, the base coat film 11 is formed.

Then, on a substrate surface provided with the base coat film 11, an amorphous silicon film (approximately 50 nm in thickness) is deposited by, for example, the plasma CVD. The amorphous silicon film is crystallized by such a technique as laser annealing to form the first semiconductor film formed of polysilicon. After that, the first semiconductor film is patterned to form, for example, the first semiconductor layers 12a and 12b, and the (pre-conductive) second protective pattern 12p.

After that, on the substrate surface provided with the first semiconductor layers 12a and 12b, a silicon oxide film (approximately 100 nm in thickness) is deposited by, for example, the plasma CVD to form the first gate insulating film 13.

Furthermore, on the substrate surface provided with the first gate insulating film 13, a first metal film such as a molybdenum film (approximately 200 nm in thickness) is formed by, for example, sputtering. After that, the first metal film is patterned to form, for example, the first gate electrodes 14a and 14b, the gate line 14g, and the light-emission control line 14e.

Then, using the first gate electrodes 14a and 14b as masks, the first semiconductor layers 12a and 12b are doped with impurity ions (e.g., phosphorus) so that portions of the first semiconductor layers 12a and 12b become conductive to form: the first conductor region 12aa, the second conductor region 12ab, and the first channel region 12ac in the first semiconductor layer 12a; and the first source region 12ba, the first drain region 12bb, and the first channel region 12bc in the first semiconductor layer 12b. Here, the second protective pattern 12p becomes conductive.

After that, on the substrate surface of the conductive portions in the first semiconductor layers 12a and 12b, a silicon nitride film (approximately 150 nm in thickness) and a silicon oxide film (approximately 100 nm in thickness) are sequentially deposited by, for example, the plasma CVD. Hence, the first interlayer insulating film 15 is formed.

Furthermore, on the substrate surface provided with the first interlayer insulating film 15, the second semiconductor film such a substance as an InGaZnO₄ film (approximately 30 nm in thickness) containing oxide semiconductor is deposited by, for example, sputtering. After that, the second semiconductor film is patterned to form the second semiconductor layers 16a and 16b, and the (pre-conductive) first protective pattern 16p.

Subsequently, on the substrate surface provided with such layers as the second semiconductor layers 16a and 16b, a silicon oxide film (approximately 100 nm in thickness) is deposited by, for example, the plasma CVD. After that, the second metal film such as a molybdenum film (approximately 200 nm in thickness) is deposited by, for example, sputtering. The second metal film is patterned to form such constituent features as the second gate electrodes 18a and 18b, and the second initialization power supply line 18i.

After that, the silicon oxide film exposed from, for example, the second gate electrodes 18a and 18b is etched to form such films as the second gate insulating films 17a and 17b.

Moreover, on the substrate surface provided with the second gate insulating films 17a and 17b, a silicon oxide film (approximately 300 nm in thickness) and a silicon nitride film (approximately 150 nm in thickness) are sequentially deposited by, for example, the plasma CVD. Hence, the second interlayer insulating film 19 is formed. Note that, by heat treatment given to the formed second interlayer insulating film 19, portions of the second semiconductor layers 16a and 16b become conductive to form: the third conductor region 16aa, the fourth conductor region 16ab, and the second channel region 16ac in the second semiconductor layer 16a; and the second source region 16ba, the second drain region 16bb, and the second channel region 16bc in the second semiconductor layer 16b. Here, the first protective pattern 16p becomes conductive.

Subsequently, the first gate insulating film 13, the first interlayer insulating film 15, and the second interlayer insulating film 19 are patterned as appropriate, so that contact holes such as the first contact holes Ha and Hh, the second contact holes Hb and Hi, the third contact holes Hc and Hj, and the fourth contact holes Hd and Hk are formed on a substrate surface of the second interlayer insulating film 19.

After that, on the substrate surface having the contact holes, a titanium film (approximately 50 nm in thickness), an aluminum film (approximately 400 nm in thickness), and a titanium film (approximately 100 nm in thickness) are sequentially deposited by, for example, sputtering to form the third metal film. After that, the third metal film is patterned to form such constituent features as the first terminal electrode 20a, the second terminal electrode 20b, the third terminal electrode 20c, the fourth terminal electrode 20d, the first source electrode 20h, the first drain electrode 20i, the second source electrode 20j, the second drain electrode 20k, the source line 20f, and the power supply line 20g.

Furthermore, on the substrate surface provided with such a constituent feature as the first terminal electrode 20a, a silicon oxide film (approximately 250 nm in thickness) is deposited by, for example, the plasma CVD to form the protective insulating film 21.

Subsequently, the substrate surface provided with the protective insulating film 21 is coated with an acrylic-based photosensitive resin film (approximately 2 μm in thickness) by, for example, spin coating or slit coating. After that, the coating film is pre-baked, exposed to light, developed, and post-baked to form the planarization film 22 having a contact hole.

Finally, the protective insulating film 21 exposed from the contact hole of the planarization film 22 is removed, so that the contact hole reaches the second terminal electrode 20b of the light-emission control TFT 9f.

As described above, the TFT layer 30 is successfully formed.

### Organic-EL-Element-Layer Forming Step

On the planarization film 22 of the TFT layer 30 formed at the TFT-layer forming step, the first electrode 31, the edge cover 32, the organic EL layer 33 (including the hole injection layer 1, the hole transport layer 2, the light-emitting layer 3, the electron transport layer 4, and the electron injection layer 5), and the second electrode 34 are formed, using a known technique. Hence, the organic-EL-element layer 40 is formed.

### Sealing-Film Forming Step

First, on a substrate surface of the organic-EL-element layer 40 formed at the organic-EL-element-layer forming step, an inorganic insulating film such as, for example, a silicon nitride film, a silicon oxide film, or a silicon oxynitride film is deposited by the plasma CVD, using a mask. Hence, the first inorganic sealing film 41 is formed.

Then, on a substrate surface of the first inorganic sealing film 41, for example, an organic resin material such as acrylic resin is deposited by inkjet printing. Hence, the organic sealing film 42 is formed.

Furthermore, on the substrate provided with the organic sealing film 42, an inorganic insulating film such as, for example, a silicon nitride film, a silicon oxide film, or a silicon oxynitride film is deposited by the plasma CVD, using a mask, to form the second inorganic sealing film 43. Hence, the sealing film 45 is formed.

Finally, a protective sheet (not shown) is attached to the substrate surface provided with the sealing film 45. After that, a laser beam is emitted from toward the glass substrate of the resin substrate 10, and the glass substrate is removed from a lower surface of the resin substrate 10. Moreover, a protective sheet (not shown) is attached to the lower surface of the resin substrate 10 from which the glass substrate is removed.

As can be seen, the organic EL display device 50 of this embodiment is successfully produced.

As described above, as to the organic EL display device 50 of this embodiment, the CMOS circuit C is disposed in the picture-frame region F to serve as a peripheral circuit. In a plan view, the CMOS circuit C is provided with: the first protective pattern 16p formed of oxide semiconductor and shaped into a loop around the first semiconductor layer 12b of the fourth peripheral TFT 9s; and the second protective pattern 12p formed of polysilicon and shaped into a loop around the second semiconductor layer 16b of the fifth peripheral TFT 9t. Thanks to such a configuration, static electricity accumulated at the production steps is likely to be discharged to the first protective pattern 16p and the second protective pattern 12p provided to serve as lightning rods, and is less likely to be discharged to the first semiconductor layer 12b and the second semiconductor layer 16b surrounded with the first protective pattern 16p and the second protective pattern 12p. Such a feature successfully reduces deterioration in characteristics of the fourth peripheral TFT 9s and the fifth peripheral TFT 9t by the discharge of the static electricity. Furthermore, water contained in the resin substrate 10 and the planarization film 22 formed of an organic resin material is physically blocked by the first protective pattern 16p and the second protective pattern 12p. Such a feature successfully keeps water from entering the first semiconductor layer 12b and the second semiconductor layer 16b surrounded with the first protective pattern 16p and the second protective pattern 12p and reduces deterioration in characteristics of the fourth peripheral TFT 9s and the fifth peripheral TFT 9t by the entrance of the water. Hence, as to the organic EL display device 50 in a hybrid structure, the feature successfully reduces deterioration in characteristics of the fourth peripheral TFT 9s and the fifth peripheral TFT 9t in the CMOS circuit C forming a portion of the gate driver M.

### Other Embodiments

The above embodiment exemplifies the organic EL display device 50 including both of the first protective pattern 16p and the second protective pattern 12P in the CMOS circuit C. The disclosure is also applicable to such devices as an organic EL display device and a liquid crystal display device each including one of the first protective pattern 16p or the second protective pattern 12p in the CMOS circuit C.

In the above embodiment, the exemplified organic EL layer has a multilayer structure including five layers such as a hole injection layer, a hole transport layer, a light-emitting layer, an electron transport layer, and an electron injection layer. Alternatively, the organic EL layer may have a multilayer structure including three layers such as, for example, a hole-injection-and-hole-transport layer, a light-emitting layer, and an electron-transport-and-electron-injection layer.

Moreover, in the above embodiment, the exemplified organic EL display device includes a first electrode as an anode and a second electrode as a cathode. The disclosure can also be applied to an organic EL display device whose multilayer structure of the organic EL layer is inverted, such that the first electrode is a cathode and the second electrode is an anode.

In addition, in the above embodiment, the organic EL display device is exemplified as a display device. The disclosure can be applied to a display device including a plurality of light-emitting elements driven by currents. For example, the disclosure can be applied to a display device including quantum-dot light-emitting diodes (QLEDs); that is, light-emitting elements including layers containing quantum dots.

### INDUSTRIAL APPLICABILITY

As described above, the disclosure is useful for a flexible display device.

1: A display device, comprising:
a base substrate;
a thin-film transistor layer provided on the base substrate and including a first thin-film transistor having a first semiconductor layer formed of polysilicon and a second thin-film transistor having a second semiconductor layer formed of oxide semiconductor;
a display region configured to display an image, and a picture-frame region defined around the display region;
a plurality of pixel thin-film transistors provided to each of a plurality of subpixels included in the display region, the plurality of pixel thin-film transistors serving as the first thin-film transistor and the second thin-film transistor; and
a complementary metal oxide semiconductor circuit included in the picture-frame region and provided to serve as a portion of a drive circuit, the complementary metal oxide semiconductor circuit being a combination of the first thin-film transistor and the second thin-film transistor,
wherein the complementary metal oxide semiconductor circuit includes, in a plan view, at least one of a first protective pattern formed of the oxide semiconductor around the first semiconductor layer of the first thin-film transistor in the complementary metal oxide semiconductor circuit or a second protective pattern formed of the polysilicon around the second semiconductor layer of the second thin-film transistor in the complementary metal oxide semiconductor circuit.

2: The display device according to claim 1,
wherein the first protective pattern is shaped into a loop to surround the first semiconductor layer of the first thin-film transistor in the complementary metal oxide semiconductor circuit.

3: The display device according to claim 2,
wherein the first protective pattern has: a portion not overlapping with a wire connected to an electrode of the first thin-film transistor in the complementary metal oxide semiconductor circuit; and a portion overlapping with the wire and shaped narrower than the portion not overlapping with the wire.

4: The display device according to claim 1,
wherein the first protective pattern surrounds the first semiconductor layer of the first thin-film transistor in the complementary metal oxide semiconductor circuit, the first protective pattern being shaped into a plurality of island shapes not to overlap with a wire connected to an electrode of the first thin-film transistor.

5: The display device according to claim 1,
wherein the second protective pattern is shaped into a loop to surround the second semiconductor layer of the second thin-film transistor in the complementary metal oxide semiconductor circuit.

6: The display device according to claim 5,
wherein the second protective pattern has: a portion not overlapping with a wire connected to an electrode of the second thin-film transistor in the complementary metal oxide semiconductor circuit; and a portion overlapping with the wire and shaped narrower than the portion not overlapping with the wire.

7: The display device according to claim 1,
wherein the second protective pattern surrounds the second semiconductor layer of the second thin-film transistor in the complementary metal oxide semiconductor circuit, the second protective pattern being shaped into a plurality of island shapes not to overlap with a wire connected to an electrode of the second thin-film transistor.

8: The display device according to claim 1,
wherein the thin-film transistor layer includes: a first semiconductor film formed of polysilicon; a first inorganic insulating film; a first metal film; a second inorganic insulating film; a second semiconductor film formed of the oxide semiconductor; a third inorganic insulating film; a second metal film; a fourth inorganic insulating film; and a third metal film, all of which are sequentially stacked on top of another,
the first semiconductor layer is formed of the first semiconductor film, and
the second semiconductor layer is formed of the second semiconductor film.

9: The display device according to claim 1, further comprising:
a light-emitting-element layer provided on the thin-film transistor layer and including a plurality of light-emitting elements arranged to correspond to the plurality of subpixels included in the display region; and
a sealing film provided on the light-emitting-element layer.

10: The display device according to claim 9,
wherein each of the light-emitting elements is an organic electroluminescent element.
